(19) United States
(12) Patent Application Publication
(10) Pub. No.: US 2012/0107996 A1
(43) Pub. Date: May 3, 2012

(54) SURFACE TREATMENT PROCESS PERFORMED ON A TRANSPARENT CONDUCTIVE OXIDE LAYER FOR SOLAR CELL APPLICATIONS

(75) Inventors: Shuran Sheng, Cupertino, CA (US); Lin Zhang, San Jose, CA (US); Zheng Yuan, Cupertino, CA (US); Yong Kee Chae, San Ramon, CA (US)

(73) Assignee: APPLIED MATERIALS, INC., Santa Clara, CA (US)

(21) Appl. No.: 12/916,526

(22) Filed: Oct. 30, 2010

(51) Int. Cl. H01L 31/18

(52) U.S. Cl. 438/71; 257/E31.13

(57) ABSTRACT

Embodiments of the invention provide methods of a surface treatment process performing on a transparent conductive oxide layer used in solar cell devices. In one embodiment, a method of performing a surface treatment process includes providing a substrate having a transparent conductive oxide layer disposed thereon in a processing chamber, supplying a gas mixture including an oxygen containing gas into the processing chamber, and performing a surface treatment process using the gas mixture on the surface of the transparent conductive oxide layer.

### BACKGROUND OF THE INVENTION

1. Field of the Invention

Embodiments of the present invention generally relate to methods of a surface treatment process performed on a surface of a transparent conductive oxide layer. More particularly, embodiments of the present invention relate to a surface treatment process performed on a surface of a transparent conductive oxide layer used in thin-film solar cell applications.

2. Description of the Related Art

Crystalline silicon solar cells and thin film solar cells are two types of solar cells. Crystalline silicon solar cells typically use either mono-crystalline substrates (i.e., single-crystal substrates of pure silicon) or multi-crystalline silicon substrates (i.e., poly-crystalline or polysilicon). Additional film layers are deposited onto the silicon substrates to improve light capture, form the electrical circuits, and protect the devices. Thin-film solar cells use thin layers of materials deposited on suitable substrates to form one or more p-n junctions. Suitable substrates include glass, metal, and polymer substrates.

To expand the economic use of solar cells, efficiency must be improved. Solar cell efficiency relates to the proportion of incident radiation converted into useful electricity. To be useful for more applications, solar cell efficiency must be improved beyond the current best performance of approximately 15%. With energy costs rising, there is a need for improved thin film solar cells and methods and apparatuses for forming the same in a factory environment.

### SUMMARY OF THE INVENTION

Embodiments of the invention provide methods of a surface treatment process performing on a transparent conductive oxide layer used in solar cell devices. In one embodiment, a method of performing a surface treatment process includes providing a substrate having a transparent conductive oxide layer disposed thereon in a processing chamber, supplying a gas mixture including an oxygen containing gas into the processing chamber, and performing a surface treatment process using the gas mixture on the surface of the transparent conductive oxide layer.

In another embodiment, a method of performing a surface treatment process includes providing a substrate having a transparent conductive oxide layer disposed thereon in a processing chamber, supplying a gas mixture including an oxygen containing gas into the processing chamber, performing a surface treatment process using the gas mixture on the surface of the transparent conductive oxide layer, and annealing the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic side-view of a tandem junction thin-film solar cell according to one embodiment of the invention;

FIG. 2 depicts a process flow diagram for performing a surface treatment process on a transparent conductive layer in accordance with one embodiment of the present invention;

FIG. 3 depicts a sequence of fabrication stages of performing a surface treatment process on a transparent conducive oxide layer in accordance with one embodiment of the present invention; and

FIG. 4 depicts a cross-sectional view of an apparatus according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Thin-film solar cells are generally formed from numerous types of films, or layers, put together in many different ways. Most films used in such devices incorporate a semiconductor element that may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, and conductivity. Most of these films can be formed by use of a chemical vapor deposition process, which may include some degree of ionization or plasma formation.

Charge generation during a photovoltaic process is generally provided by a bulk semiconductor layer, such as a silicon containing layer. The bulk layer is also sometimes called an intrinsic layer to distinguish it from the various doped layers present in the solar cell. The intrinsic layer may have any desired degree of crystallinity, which will influence its light-absorbing characteristics. For example, an amorphous intrinsic layer, such as amorphous silicon, will generally absorb light at different wavelengths from intrinsic layers having different degrees of crystallinity, such as microcrystalline or nanocrystalline silicon. For this reason, it is advantageous to use both types of layers to yield the broadest possible absorption characteristics.

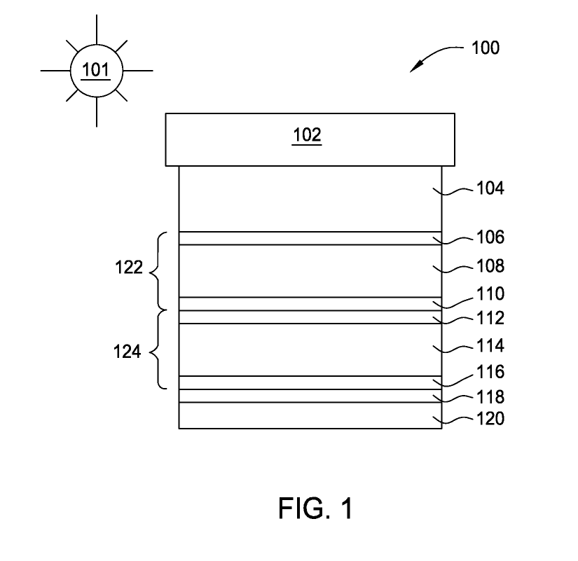

FIG. 1 is a schematic diagram of an embodiment of a multi-junction solar cell 100 oriented toward a light or solar radiation 101. The solar cell 100 includes a substrate 102. A first transparent conducting oxide (TCO) layer 104 formed over the substrate 102, a first p-i-n junction 122 formed over the first TCO layer 104. A second p-i-n junction 124 formed over the first p-i-n junction 122, a second TCO layer 118 formed over the second p-i-n junction 124, and a metal back layer 120 formed over the second TCO layer 118. The substrate 102 may be a glass substrate, polymer substrate, metal substrate, or other suitable substrate, with thin films formed thereover.

The first TCO layer 104 and the second TCO layer 118 may each comprise tin containing material, zinc containing material, tin oxide, zinc oxide, indium tin oxide, cadmium stannate, combinations thereof, or other suitable materials. It is understood that the TCO materials may also additionally include dopants. For example, the TCO materials may further include dopants, such as tin, aluminum, gallium, boron, and other suitable dopants.

In one embodiment, aluminum containing materials, boron containing materials, titanium containing materials, tantalum containing materials, tungsten containing materials, alloys thereof, combinations thereof and the like may be formed in the TCO materials. In one embodiment, the TCO material is a zinc containing material having aluminum containing material doped therein. In one embodiment, the dopant formed within the zinc containing material is an aluminum oxide. The aluminum oxide dopant forms an aluminum oxide doped a zinc oxide (AZO) layer as the transparent conductive layer oxide 104 on the substrate surface. In one embodiment, the transparent conductive oxide layer 104 is an aluminum oxide doped zinc oxide (AZO) layer having an aluminum oxide dopant concentration between about 0.25 percent by weight and about 3 percent by weight formed in the zinc oxide layer. In one embodiment, the transparent conductive oxide layer 104 may have a thickness between about 5000 Å and about 12000 Å. Zinc oxide, in one embodiment, comprises 5 atomic % or less of dopants, for example about 2.5 atomic % or less aluminum. In certain instances, the substrate 102 may be provided by the glass manufacturers with the first TCO layer 104 already deposited thereon. In one embodiment, this transparent conductive oxide layer 104 may be formed by a sputter process, a PVD process, a LPCVD process, CVD process, plating process, coating process, or any other suitable process as needed.

Referring back to FIG. 1, the first p-i-n junction 122 may comprise a p-type silicon containing layer 106, an intrinsic type silicon containing layer 108 formed over the p-type silicon containing layer 106, and an n-type silicon containing layer 110 formed over the intrinsic type silicon containing layer 108. In certain embodiments, the p-type silicon containing layer is a p-type amorphous silicon layer 106 having a thickness between about 60 Å and about 300 Å. In certain embodiments, the intrinsic type silicon containing layer 108 is an intrinsic type amorphous silicon layer having a thickness between about 1,500 Å and about 3,500 Å. In certain embodiments, the n-type silicon containing layer is a n-type microcrystalline silicon layer may be formed to a thickness between about 100 Å and about 400 Å.

The second p-i-n junction 124 may comprise a p-type silicon containing layer 112 and an intrinsic type silicon containing layer 114 formed over the p-type silicon containing layer 112, and a n-type silicon containing layer 116 formed over the intrinsic type silicon containing layer 114. In certain embodiments, the p-type silicon containing layer 112 may be a p-type microcrystalline silicon layer 112 having a thickness between about 100 Å and about 400 Å. In certain embodiments, the intrinsic type silicon containing layer 114 is an intrinsic type microcrystalline silicon layer having a thickness between about 10,000 Å and about 30,000 Å. In certain embodiments, the n-type silicon containing layer 116 is an amorphous silicon layer having a thickness between about 100 Å and about 500 Å.

The metal back layer 120 may include, but not limited to a material selected from the group consisting of Al, Ag, Ti, Cr, Au, Cu, Pt, alloys thereof, and combinations thereof. Other processes may be performed to form the solar cell 100, such a laser scribing processes. Other films, materials, substrates, and/or packaging may be provided over metal back layer 120 to complete the solar cell device. The formed solar cells may be interconnected to form modules, which in turn can be connected to form arrays.

Solar radiation 101 is primarily absorbed by the intrinsic layers 108, 114 of the p-i-n junctions 122, 124 and is converted to electron-holes pairs. The electric field created between the p-type layer 106, 112 and the n-type layer 110, 116 that stretches across the intrinsic layer 108, 114 causes electrons to flow toward the n-type layers 110, 116 and holes to flow toward the p-type layers 106, 112 creating a current. The first p-i-n junction 122 may comprise an intrinsic type amorphous silicon layer 108 and the second p-i-n junction 124 may comprise an intrinsic type microcrystalline silicon layer 114 to take advantage of the properties of amorphous silicon and microcrystalline silicon which absorb different wavelengths of the solar radiation 101. Therefore, the formed solar cell 100 is more efficient, as it captures a larger portion of the solar radiation spectrum. The intrinsic layer 108, 114 of amorphous silicon and the intrinsic layer of microcrystalline are stacked in such a way that solar radiation 101 first strikes the intrinsic type amorphous silicon layer 108 and then strikes the intrinsic type microcrystalline silicon layer 114, since amorphous silicon has a larger bandgap than microcrystalline silicon. Solar radiation not absorbed by the first p-i-n junction 122 is transmitted to the second p-i-n junction 124.

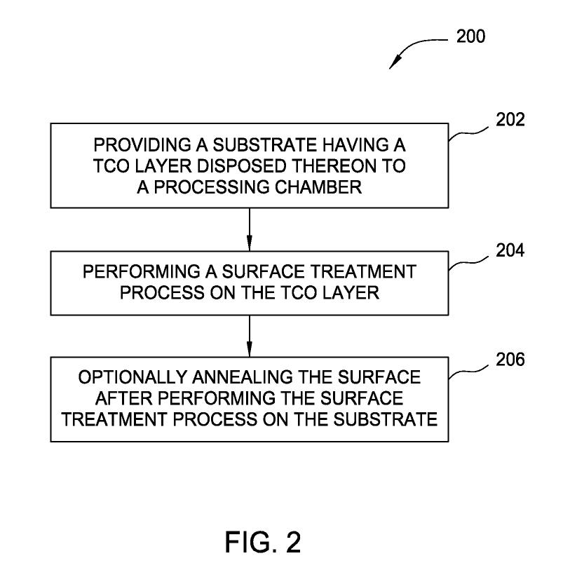

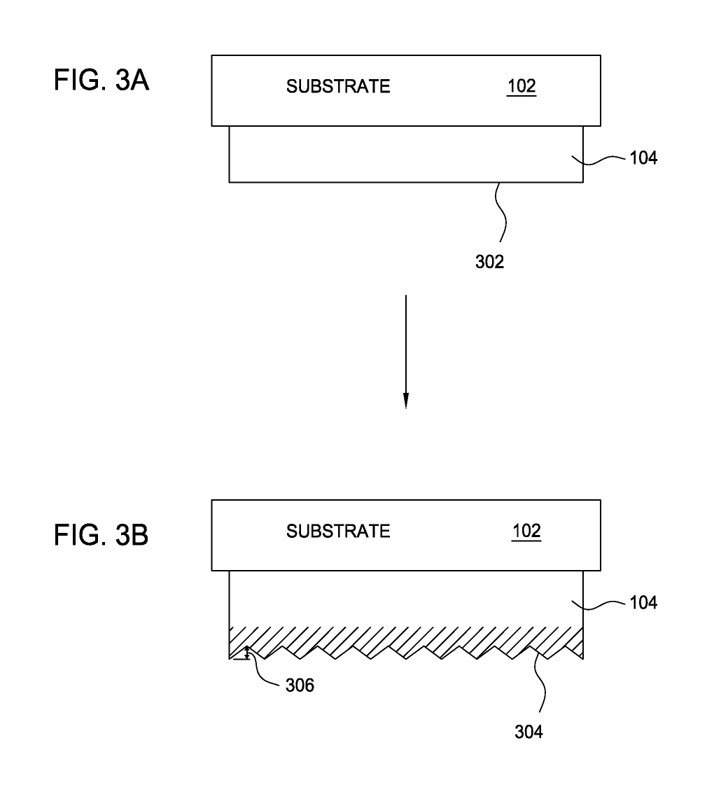

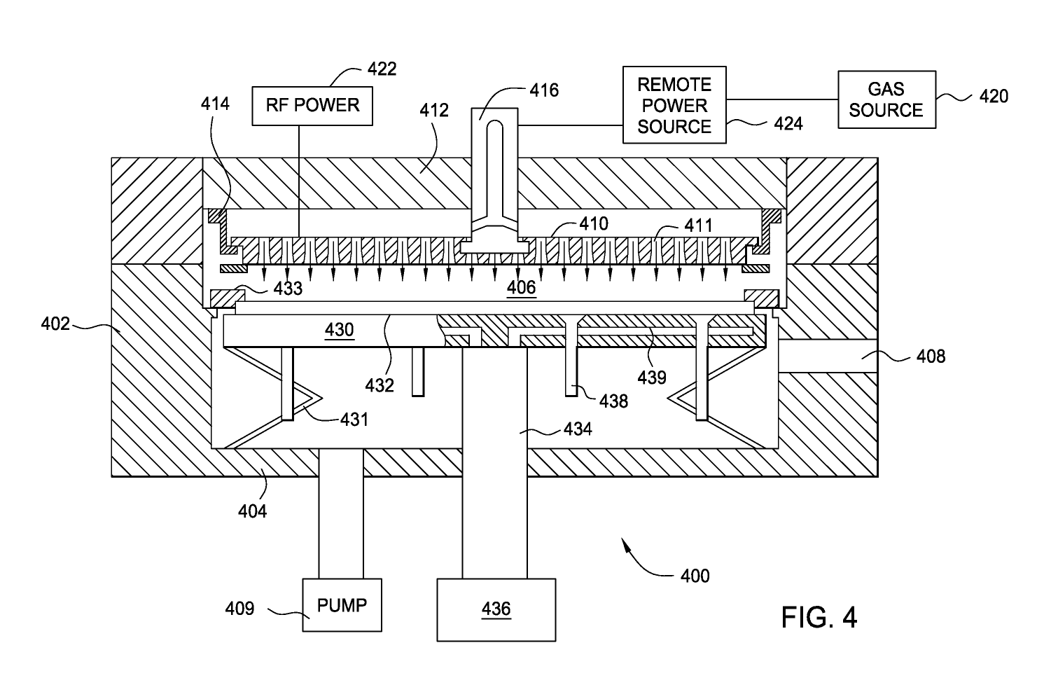

FIG. 2 depicts a flow diagram of one embodiment of performing a surface treatment process 200 on a transparent conductive oxide layer, such as the transparent conductive oxide layer 104, as depicted in FIG. 1. The process may be performed in a processing chamber that performs the subsequent deposition process, such as a processing chamber utilized to form the p-type layer 106, as depicted in FIG. 1. One exemplary embodiment of the processing chamber of performing the surface treatment process will be further discussed below with referenced to FIG. 4. In another embodiment, the surface treatment process 200 may be performed in the processing chamber in which the transparent conductive oxide layer 104 is formed, such as a PVD chamber, a sputter chamber, a plating chamber, or any other suitable coating chamber. In yet another embodiment, the surface treatment process 200 may be performed in a suitable chamber different from the deposition chambers in which the transparent conductive oxide layer 104 and the p-type layer 106 are formed. FIGS. 3A-3B are schematic cross-sectional views of a portion of the substrate 102 having a transparent conductive oxide layer formed thereon corresponding to various stages of the surface treatment process 200. Although the surface treatment process 200 may be illustrated for performing on a surface of the transparent conductive oxide layer 104, the surface treatment process 200 may be beneficially utilized to perform on other structures.

The process 200 begins at step 202 by transferring (i.e., providing) the substrate 102, as shown in FIG. 3A, to a processing chamber. In the embodiment depicted in FIG. 3A, the substrate 102 may be thin sheet of metal, plastic, organic material, silicon, glass, quartz, or polymer, or other suitable material. The substrate 102 may have a surface area greater than about 1 square meters, such as greater than about 6 square meters. Alternatively, the substrate 102 may be configured to form thin film PV solar cell, or other types of solar cells, such as crystalline, microcrystalline or other type of silicon-based thin films as needed. In one embodiment, the substrate 102 may have a transparent conductive oxide layer 104 formed thereon readily to perform the surface treatment process thereon.

At step 204, a surface treatment process is performed on the transparent conductive oxide layer 104 disposed on the substrate 102, as shown in FIG. 3B. In one embodiment, the surface treatment process is performed to incorporate oxygen elements into the transparent conductive oxide layer 104. It is believed that the oxygen elements incorporated into the surface of the transparent conductive oxide layer 104 may increase the film transparency of the transparent conductive oxide layer 104, thereby improving the amount of light passing therethrough to the p-i-n junctions 122, 124. Furthermore, it is also believed that the oxygen elements incorporated into the transparent conductive oxide layer 104 can increase surface work function by reducing the oxygen vacancy on the surface of the transparent conductive oxide layer 104, thereby increasing the overall electrical performance and conversion efficiency of the solar cell devices incorporating the junctions 122, 124. The post treatment process may also assist removing contaminant from the surface of the transparent conductive oxide layer, thereby providing a good contact interface between the transparent conductive oxide layer 104 and the p-type silicon containing layer 106 subsequently formed thereon. Furthermore, the post treatment process may also be performed to modify the morphology and/or surface roughness of the surface of the transparent conductive layer 104 to improve light trapping capability. In one embodiment, the post treatment process may create a roughened surface 304 having a surface roughness 306 between about 100 Å and about 1000 Å.

In one embodiment, the oxygen element incorporated into the transparent conductive oxide layer 104 may have a dopant concentration up to about 5 percent by weight. The oxygen elements may be incorporated into the transparent conductive oxide layer 104 at a depth over 50 nm of the transparent conductive oxide layer.

In one embodiment, the surface treatment process may be performed by supplying a gas mixture including an oxygen containing gas into the processing chamber. The oxygen containing gas may be selected from the group consisting of N₂O, NO₂, O₂, O₃, H₂O, CO₂, CO, clean air and the like. In one exemplary embodiment, the oxygen containing gas used to perform the substrate treatment process is NO₂ gas.

In one embodiment, the surface treatment process may be in the form of a plasma process or a thermal process. In the embodiment wherein a plasma process is employed, the substrate 102 may be provided into a plasma chamber. Subsequently, the oxygen containing gas may be supplied into the plasma chamber to form a plasma from the gas mixture so as to perform the substrate treatment process on the transparent conductive oxide layer 104.

In another embodiment, the surface treatment process may be performed in the form of a thermal process. In this embodiment, a thermal energy is provided to the substrate. The oxygen containing gas mixture is supplied in the chamber. The heated substrate is exposed to oxygen containing gas to undergo the thermal energy treatment process. It is noted that the substrate temperature is controlled during the thermal process between about 200 degrees Celsius and about 500 degrees Celsius within a range less than the glass melting point so as to prevent thermal damage to the substrate 102. In an exemplary embodiment described herein, the surface treatment process performed on the transparent conductive oxide layer 104 is a surface plasma treatment process.

Several process parameters may be controlled while performing the surface plasma treatment process. The gas flow for supplying the oxygen containing gas is between about 3 sccm/L and about 100 sccm/L, such as between about 10 sccm/L and about 50 sccm/L, for example about 20 sccm/L and about 35 sccm/L. The RF power supplied to do the treatment process may be controlled at between about 50 milliWatts/cm² and about 500 milliWatts/cm², such as about 70 milliWatts/cm², may be provided to the showerhead 20 milliWatts/cm² and about 500 milliWatts/cm², such as about 350 milliWatts/cm² for surface treatment process.

In another embodiment, the surface treatment process may be performed by providing a gas mixture including a reducing gas to treat the surface of the transparent conductive oxide layer 104 so as to densify, remove surface contamination and decrease work function of the transparent conductive oxide layer 104. Suitable examples of the reducing gas including NH₃, H₂ or other suitable gas. Furthermore, in certain embodiment, an inert gas may be used to perform the surface treatment process. The inert gas may not only assist removing containment from the surface of the transparent conductive oxide layer 104, but also assist densifying and alerting the surface properties of the transparent conductive oxide layer. Examples of the inert gas include Ar, He or the like. It is noted that the process parameters used to perform the surface treatment process by using the oxygen containing gas may be configured to be similar with the process parameters for using the reducing gas or inert gas.

At step 206, after the surface treatment process is performed on the substrate, an optional annealing process may be performed. The anneal process may be performed to assist driving oxygen elements (or other elements incorporated into the transparent conductive oxide layer 104 during the surface treatment process) deeper into the treated transparent conductive oxide layer 104. The annealing process may also assist repairing defects or damage caused during the surface treatment process performed at step 204. In one embodiment, the annealing process may be performed in any suitable thermal processing chamber, such as a RTP chamber, a furnace tube, a plasma chamber, a laser annealing chamber, or any other suitable process that may provide thermal energy to the substrate. The annealing process may be performed at a temperature between about 200 degrees Celsius and about 500 degree Celsius to assist in the densification and/or repairing damage formed on the surface of the transparent conductive oxide layer 104 formed on the substrate 102.

In one embodiment, the optional annealing process may be performed for about 30 second to about 3600 seconds, for example, about 60 seconds to about 1800 seconds, such as about 120 seconds to about 900 seconds. At least one annealing gas is supplied into the annealing chamber for thermal annealing process. Examples of annealing gases include oxygen (O₂), ozone (O₃), atomic oxygen (O), water (H₂O), nitric oxide (NO), nitrous oxide (N₂O), nitrogen dioxide (NO₂), dinitrogen pentoxide (N₂O₅), nitrogen (N₂), ammonia (NH₃), hydrazine (N₂H₄), Ar, He, derivatives thereof or combinations thereof. In one example of a thermal annealing process, the substrate 102 is annealed to a temperature of about 400 degrees Celsius for about 1800 seconds within a 5% hydrogen in nitrogen atmosphere. It is believed that the thermal annealing process may assist repairing and reconstructing the atomic lattices of the treated transparent conductive oxide layer 104. The thermal annealing process also drives out the dangling bond and reconstruct the film bonding structure, thereby reducing film resistivity, improving film mobility and film transparency, and promoting the film qualities and overall device performance.

FIG. 4 is a schematic cross-section view of one embodiment of a plasma enhanced chemical vapor deposition (PECVD) chamber 400 in which a surface treatment process may be performed therein. It is noted that FIG. 4 is just an exemplary apparatus that may be used to perform the surface treatment process on the transparent conductive oxide layer 104 as discussed above with referenced to FIGS. 1-3. Other suitable apparatus, including sputtering chamber, PVD chamber, thermal chamber, annealing chamber, coating chamber, plating chamber or any suitable chamber may also be utilized to perform the surface treatment process as needed. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 400 generally includes walls 402, a bottom 404, and a showerhead 410, and substrate support 430 which define a process volume 406. The process volume is accessed through a valve 408 such that the substrate, may be transferred in and out of the chamber 400. The substrate support 430 includes a substrate receiving surface 432 for supporting a substrate and stem 434 coupled to a lift system 436 to raise and lower the substrate support 430. A shadow ring 433 may be optionally placed over periphery of the substrate 102. Lift pins 438 are moveably disposed through the substrate support 430 to move a substrate to and from the substrate receiving surface 432. The substrate support 430 may also include heating and/or cooling elements 439 to maintain the substrate support 430 at a desired temperature. The substrate support 430 may also include grounding straps 1131 to provide RF grounding at the periphery of the substrate support 430.

The showerhead 410 is coupled to a backing plate 412 at its periphery by a suspension 414. The showerhead 410 may also be coupled to the backing plate by one or more center supports 416 to help prevent sag and/or control the straightness/curvature of the showerhead 410. A gas source 420 is coupled to the backing plate 412 to provide gas through the backing plate 412 and through the showerhead 410 to the substrate receiving surface 432. A vacuum pump 409 is coupled to the chamber 400 to control the process volume 406 at a desired pressure. An RF power source 422 is coupled to the backing plate 412 and/or to the showerhead 410 to provide a RF power to the showerhead 410 so that an electric field is created between the showerhead and the substrate support 430 so that a plasma may be generated from the gases between the showerhead 410 and the substrate support 430. Various RF frequencies may be used, such as a frequency between about 0.3 MHz and about 200 MHz. In one embodiment the RF power source is provided at a frequency of 13.56 MHz.

A remote plasma source 424, such as an inductively coupled remote plasma source, may also be coupled between the gas source and the backing plate. Between processing substrates, a cleaning gas may be provided to the remote plasma source 424 so that a remote plasma is generated and provided to clean chamber components. The cleaning gas may be further excited by the RF power source 422 provided to the showerhead. Suitable cleaning gases include but are not limited to NF₃, F₂, and SF₆.

In one embodiment, the heating and/or cooling elements 439 may be set to provide a substrate support temperature during deposition of about 400° C. or less, for example between about 100° C. and about 400° C. or between about 150° C. and about 300° C., such as about 200° C.

The spacing during deposition between the top surface of a substrate disposed on the substrate receiving surface 432 and the showerhead 410 may be between 400 mil and about 1,200 mil, for example between 400 mil and about 800 mil.

Thus, an apparatus and methods for performing a surface treatment process on a surface of a transparent conductive oxide layer are provided. The surface treatment process as performed may assist incorporating desired elements into a desired depth from a surface of the transparent conductive oxide layer, thereby efficiently improving film transparency, mobility and device electric performance so that high conversion efficiency solar cell devices may be obtained.

While the foregoing is directed to embodiments of the present invention, other and further embodiments of the invention may be devised without departing from the basic scope thereof, and the scope thereof is determined by the claims that follow.

1. A method of performing a surface treatment process, comprising:
transferring a substrate having a transparent conductive oxide layer disposed thereon in a processing chamber, wherein the transparent conductive oxide layer is a zinc containing material having aluminum containing material doped therein;
supplying a gas mixture including an oxygen containing gas into the processing chamber; and
performing a surface treatment process at a temperature between about 200 degrees Celsius and about 500 degrees Celsius using the gas mixture on the surface of the transparent conductive oxide layer.

2. The method of claim 1, wherein performing the surface treatment process further includes:
forming a plasma from the gas mixture to treat the surface of the transparent conductive oxide layer.

3. The method of claim 1, wherein performing the surface treatment process further includes:
incorporating oxygen elements from the gas mixture into the surface of the transparent conductive oxide layer.

4. The method of claim 3, wherein the oxygen elements is incorporated into a depth over 500 Å from the surface of the transparent conductive oxide layer.

5. The method of claim 1, wherein the oxygen containing gas is selected from a group consisting of N₂O, NO₂, O₂, O₃, H₂O, CO₂, CO and clean air.

6. The method of claim 2, wherein forming a plasma from the gas mixture further comprises:
applying a RF power between about 25 milliWatts/cm² and about 500 milliWatts/cm² into the processing chamber.

7. (canceled)

8. The method of claim 1, wherein heating the substrate further comprising:
exposing the surface of the transparent conductive oxide layer to the oxygen containing gas while heating the substrate and incorporate oxygen into a depth over 500 Å from the surface of the transparent conductive layer.

9. The method of claim 3, wherein the oxygen element incorporated into the transparent conductive oxide layer has a dopant concentration over about 5 percent by weight.

10. The method of claim 2, wherein forming the plasma further comprises:
plasma treating the surface of the transparent conductive oxide layer to create a roughened surface having a surface roughness between about 100 Å and about 1000 Å.

11. The method of claim 1, further comprising:
annealing the substrate at a temperature at between about 200 degrees Celsius and about 500 degrees Celsius.

12. The method of claim 1, wherein the processing chamber is a plasma enhanced CVD chamber or a sputter chamber.

13. A method of performing a surface treatment process, comprising:
transferring a substrate having a transparent conductive oxide layer disposed thereon in a processing chamber, wherein the transparent conductive oxide layer is a zinc containing material having aluminum containing material doped therein;
supplying a gas mixture including an oxygen containing gas into the processing chamber;
performing a surface treatment process at a temperature between about 200 degrees Celsius and about 500 degrees Celsius using the gas mixture on the surface of the transparent conductive oxide layer; and
annealing the substrate at a temperature between about 200 degrees Celsius and about 500 degrees Celsius.

14. The method of claim 13, wherein the oxygen containing gas is selected from a group consisting of N₂O, NO₂, O₂, O₃, H₂O, CO₂ and CO.

15. The method of claim 13, performing the surface treatment process further includes:
forming a plasma from the gas mixture to treat the surface of the transparent conductive oxide layer.

16. The method of claim 13, wherein performing the surface treatment process further includes:
incorporating oxygen elements from the gas mixture into the surface of the transparent conductive oxide layer.

17. The method of claim 16, wherein the oxygen elements is incorporated into a depth over about 500 Å from the surface of the transparent conductive oxide layer.

18. (canceled)

19. The method of claim 16, wherein the oxygen element incorporated into the transparent conductive oxide layer has a dopant concentration over 5 percent by weight.

20. The method of claim 13, wherein the oxygen containing gas is N₂O.

21. The method of claim 1, further comprising:
forming a p-type silicon containing layer on the treated transparent conductive oxide layer to form a solar cell device structure.

22. The method of claim 13, further comprising:
forming a p-type silicon containing layer on the treated transparent conductive oxide layer to form a solar cell device structure.
